(19) United States
(12) Patent Application Publication
(10) Pub. No.: US 2026/0282545 A1
(43) Pub. Date: Sep. 17, 2026

(54) PIXEL CIRCUIT BOARD, DISPLAY DEVICE, AND METHOD FOR MANUFACTURING PIXEL CIRCUIT BOARD

(71) Applicant: Sharp Display Technology Corporation, Kameyama City, Mie (JP)

(72) Inventor: Junichi YAMADA, Kameyama City, Mie (JP)

(21) Appl. No.: 19/163,143

(22) PCT Filed: Mar. 23, 2023
(86) PCT No.: PCT/JP2023/011421

§ 371 Date: Sep. 8, 2025

(51) Int. Cl. H10D 86/40; G09G 3/32; H10D 86/60; H10H 29/01; H10H 29/49

(52) U.S. Cl. CPC H10D 86/443; G09G 3/32; H10D 86/60; G09G 2300/0426; G09G 2300/0819; G09G 2330/04; H10H 29/012; H10H 29/49

(57) ABSTRACT

A pixel circuit board (1) includes: a first power supply line (14) provided in an inactive area (10); a first power supply transistor (T5) provided in an active area (30) and connected with a pixel power supply line (32); a first control line (En) extending from the inactive area (10) to the active area (30) and being electrically connected with a gate electrode (DG) of the first power supply transistor (T5); and a first protection transistor (T16) provided in the inactive area (10) and electrically connected with the first control line (En) and the first power supply line (14).

### TECHNICAL FIELD

The present disclosure relates to a pixel circuit board, a display device, and a method for manufacturing a pixel circuit board.

### BACKGROUND ART

Patent Literature 1 discloses a light emitting device including an electrostatic protection circuit that includes a diode via which a scanning line is connected with a high-potential logic power wiring line and a diode via which the scanning line is connected with a low-potential logic power wiring line.

### CITATION LIST

### Patent Literatures

Patent Literature 1

Japanese Patent Application Publication, Tokukai, No. 2008-282029

### SUMMARY

### Technical Problem

With the above-discussed known technique, a protection resistor connected with the diode is necessary. This makes it difficult to downsize an inactive area, disadvantageously.

### Solution to Problem

A pixel circuit board in accordance with an aspect of the present disclosure includes: an active area including a plurality of pixel circuits; an inactive area provided along an outer periphery of the active area; a first power supply line which is provided in the inactive area; a first power supply transistor which is provided in the active area and which is electrically connected with a pixel power supply line; a first control line which extends from the inactive area to the active area and which is electrically connected with a gate electrode of the first power supply transistor; and a first protection transistor which is provided in the inactive area and which is electrically connected with the first control line and the first power supply line.

### Advantageous Effects of Invention

In accordance with an aspect of the present disclosure, it is possible to downsize an inactive area.

### BRIEF DESCRIPTION OF DRAWINGS

FIG. 1 is a view schematically illustrating a display device in accordance with an embodiment of the present disclosure.

FIG. 2 is a circuit diagram illustrating an example of a pixel circuit provided to a pixel circuit board in accordance with the embodiment of the present disclosure.

FIG. 3 is a circuit diagram schematically illustrating the pixel circuit board in accordance with the embodiment of the present disclosure.

FIG. 4 is a circuit diagram schematically illustrating a circuit which is being manufactured to obtain the pixel circuit board in accordance with the embodiment of the present disclosure.

FIG. 5 is a plan view illustrating an example of the pixel circuit board in accordance with the embodiment of the present disclosure.

FIG. 6 is a cross-sectional view taken along line A-A in FIG. 5.

FIG. 7 is a view schematically illustrating an area B shown in FIG. 5.

FIG. 8 is an explanatory drawing illustrating an example of a pixel circuit board in accordance with an embodiment of the present disclosure.

### DESCRIPTION OF EMBODIMENTS

The following description will discuss embodiments in accordance with the present disclosure with reference to drawings. Note that the drawings are illustrated schematically. Correlation relations between sizes and positions of images illustrated in different drawings are not always accurate, and can be changed as appropriate. Further, in explanations given below, similar or identical constituent elements will be given similar or identical reference signs.

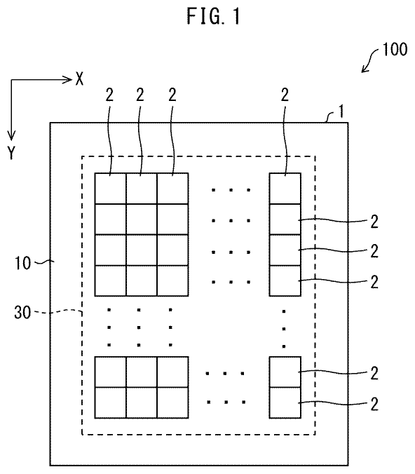

FIG. 1 is a view schematically illustrating a display device 100 in accordance with an embodiment of the present disclosure. As illustrated in FIG. 1, the display device 100 includes a pixel circuit board 1 including a plurality of pixel circuits 2. Each of the plurality of pixel circuits 2 is connected with a light emitting element ED (not illustrated) of the display device 100. The pixel circuit board 1 includes an inactive area 10 and an active area 30. The active area 30 of the pixel circuit board 1 is an area including the plurality of pixel circuits 2 that control a plurality of light emitting elements ED (not illustrated). Sub pixels are respectively arranged at locations corresponding to the plurality of light emitting elements ED. The inactive area 10 of the pixel circuit board 1 is present along an outer periphery of the active area 30. Hereinafter, for convenience of explanation, a sub-pixel row direction X and a sub-pixel column direction Y of the pixel circuit board 1 and the display device 100 are defined as indicated by the arrows in FIG. 1.

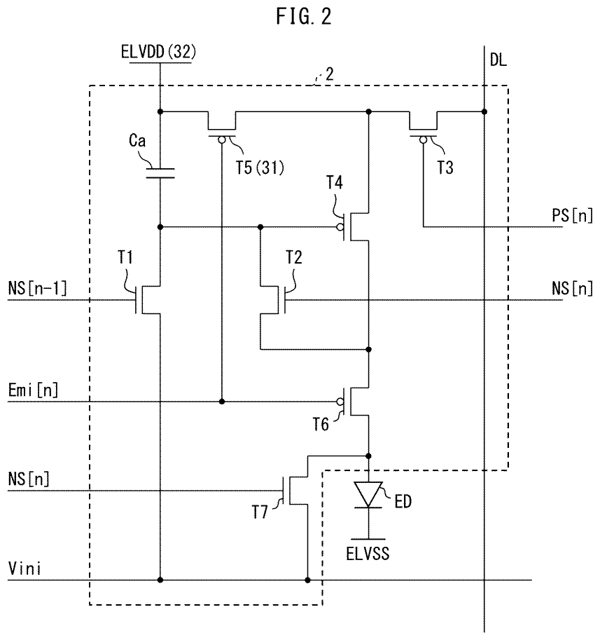

FIG. 2 is a circuit diagram illustrating an example of a pixel circuit provided to the pixel circuit board in accordance with the embodiment of the present disclosure. Each of the pixel circuits 2 illustrated in FIG. 2 has a 7T1C structure, and includes a driving transistor T4, a power supply transistor T5 (31), and a light-emission control transistor T6. The pixel circuit 2 is connected with the light emitting element ED. In FIG. 2, a source of the driving transistor T4 (P-channel) is connected with an ELVDD power source 32 via the transistor T5 (31), and is also connected with a data signal line DL via a write-in transistor T3 (P-channel). A drain of the driving transistor T4 is connected with an anode of the light emitting element ED via the light-emission control transistor T6 (P-channel), and is also connected with a gate of the driving transistor T4 via a threshold compensation transistor T2 (N-channel). A gate of the driving transistor T4 is connected with the ELVDD power source 32 via a capacity element Ca, and is also connected with an initialization power supply line Vini via an initialization transistor T1 (N-channel). A drain of the light-emission control transistor T6 is connected with the initialization power supply line Vini via a reset transistor T7 (N-channel). A gate of the initialization transistor T1 is supplied with a negative scanning signal NS[n−1] of a former stage, gates of the threshold compensation transistor T2 and the reset transistor T7 are supplied with a negative scanning signal NS[n] of their own stage, a gate of the write-in transistor T3 is supplied with a positive scanning signal PS[n] of its own stage, and gates of the power supply transistor T5 and the light-emission control transistor T6 are supplied with a light-emission control signal Emi of their own stage. Each of the transistors T3 to T6 may be a polysilicon transistor, and each of the transistors T1, T2, and T7 may be an oxide semiconductor transistor.

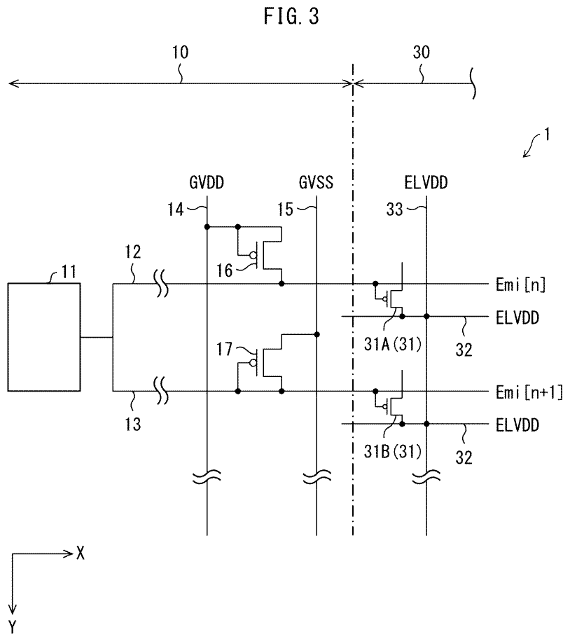

FIG. 3 is a circuit diagram schematically illustrating the pixel circuit board in accordance with the embodiment of the present disclosure. The pixel circuit board 1 includes a driver circuit 11, a first control line 12, a second control line 13, a first power supply line 14, a second power supply line 15, a first protection transistor 16, a second protection transistor 17, a power supply transistor 31, a pixel power supply line 32, and an auxiliary power supply line 33.

The driver circuit 11 is a driver circuit for a light-emission control signal Emi. At least one driver circuit 11 is included in the inactive area 10 of the pixel circuit board 1. In the pixel circuit board 1, a plurality of control lines are provided for respective sub pixel rows. The plurality of control lines include the same numbers of the first control lines 11 and the second control lines 13 as the number of the driver circuits 11. Each of the driver circuits 11 is connected with a plurality of control lines including the first control line 12 and the second control line 13. The plurality of control lines including the first control line 12 and the second control line 13 extend from the inactive area 10 to the active area 30. The plurality of control lines including the first control line 12 and the second control line 13 are electrically connected with each other.

In the active area 30 of the pixel circuit board 1, the power supply transistors 31 are provided to the sub pixels corresponding to the light emitting elements ED, respectively. The first control line 12 is a light-emission control line which carries out light-emission control for an n-th sub pixel row, and is electrically connected with a gate electrode of the power supply transistor 31. The gate electrode of the power supply transistor 31 provided for the n-th sub pixel row receives, via the first control line 12, a light-emission control signal Emi[n] output from the driver circuit 11. The second control line 13 is a light-emission control line which carries out light-emission control for a sub pixel row which is not the one for the n-th sub pixel row, for example, for an n+1-th sub pixel row, and is electrically connected with the gate electrode of the power supply transistor 31. The gate electrode of the power supply transistor 31 provided for the n+1-th sub pixel row receives, via the second control line 13, a light-emission control signal Emi[n+1] output from the driver circuit 11. As discussed above, the plurality of control lines including the first control line 12 and the second control line 13 are electrically connected with each other, and the light-emission control signals Emi[n], Emi[n+1], . . . output from the single driver circuit 11 to the plurality of control lines are the same. Hereinafter, a power supply transistor 31 whose gate electrode is connected with the first control line 12 may sometimes be referred to as a “first power supply transistor 31A”. Meanwhile, a power supply transistor 31 whose gate electrode is connected with the second control line 13 may sometimes be referred to as a “second power supply transistor 31B”.

The inactive area 10 of the pixel circuit board 1 includes, in addition to the driver circuits 11, scanning signal line driving circuits 20 (not illustrated in FIG. 3). The scanning signal line driving circuits 20 are provided for the respective sub pixel rows. A scanning signal line driving circuit 20 provided for the n-th sub pixel row outputs a scanning signal NS[n] to a scanning signal line of the n-th sub pixel row.

The first power supply line 14 and the second power supply line 15 are provided in the inactive area 10 of the pixel circuit board 1. The first power supply line 14 is a high-potential power supply line for the driver circuit 11. The second power supply line 15 is a low-potential power supply line for the driver circuit 11.

The first protection transistor 16 and the second protection transistor 17 are provided in the inactive area 10. The first protection transistor 16 is electrically connected with the first control line 12 and the first power supply line 14. To be more specific, the first protection transistor 16 is of a p-channel type, and the first protection transistor 16 has a source electrode, a drain electrode, and a gate electrode, one of the source electrode and the drain electrode being connected with the first control line 12, and the other of the source electrode and the drain electrode as well as the gate electrode being connected with the first power supply line 14. For example, the gate electrode and the drain electrode of the first protection transistor 16 are connected with the first power supply line 14, and the drain electrode of the first protection transistor 16 is connected with the first control line 12.

The second protection transistor 17 is electrically connected with the second control line 13 and the second power supply line 15. To be more specific, the second protection transistor 17 is of a p-channel type, and the second protection transistor 17 has a source electrode, a drain electrode, and a gate electrode, one of the source electrode and the drain electrode being connected with the second power supply line 15, and the other of the source electrode and the drain electrode as well as the gate electrode being connected with the second control line 13. For example, the gate electrode and the drain electrode of the second protection transistor 17 are connected with the second control line 13, and the source electrode of the second protection transistor 17 is connected with the second power supply line 15.

The first power supply transistor 31A and the second power supply transistor 31B are provided in the active area 30, and either of the source electrodes and drain electrodes thereof are electrically connected with the respective pixel power supply lines 32. The pixel power supply lines 32 are electrically connected with the auxiliary power supply line 33. Each of the pixel power supply lines 32 and the auxiliary power supply line 33 is a high-potential power supply line for a sub pixel located in the active area 30 of the pixel circuit board 1. The pixel power supply lines 32 extend along the sub-pixel row direction, and are connected with the sub pixels aligned along the sub-pixel row direction X.

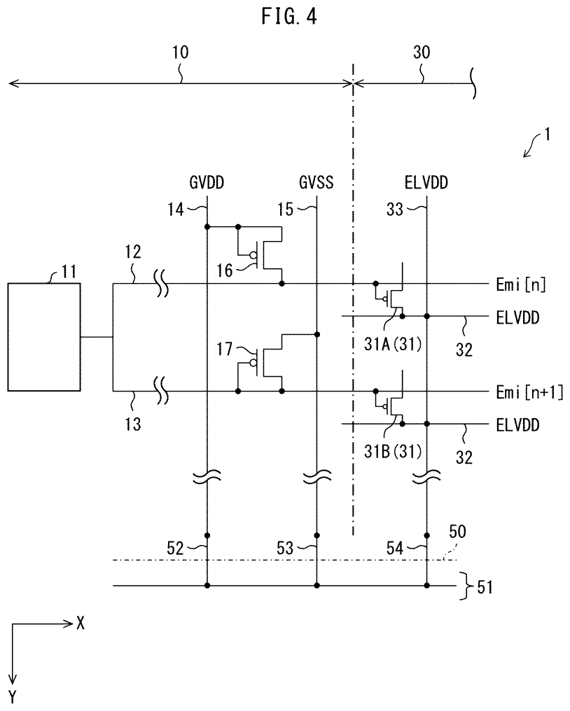

FIG. 4 is a circuit diagram schematically illustrating a circuit which is being manufactured to obtain the pixel circuit board in accordance with an embodiment of the present disclosure. As shown in FIG. 4, the pixel circuit board 1 which is being manufactured includes a short ring 51, a first connection wiring line 52, a second connection wiring line 53, and a third connection wiring line 54. The first connection wiring line 52, the second connection wiring line 53, and the third connection wiring line 54 are made of conductive silicon.

Via the first connection wiring line 52, the short ring 51 and the first power supply line 14 are electrically connected with each other. Via the second connection wiring line 53, the short ring 51 and the second power supply line 15 are electrically connected with each other. Via the third connection wiring line 54, the short ring 51 and the auxiliary power supply line 33 are electrically connected with each other. The third connection wiring line 54 includes a wiring line via which a conductive layer in which the auxiliary power supply line 33 is provided and a conductive layer in which the first power supply line 14 and the second power supply line 15 are provided are connected with each other.

The first power supply line 14, the second power supply line 15, and the auxiliary power supply line 33, which are respectively connected to the short ring 51 via the first connection wiring line 52, the second connection wiring line 53, and the third connection wiring line 54, are electrically connected with each other via the short ring 51. Until the pixel circuit board 1 is divided into pieces, the first power supply line 14, the second power supply line 15, and the auxiliary power supply line 33 are electrically connected with each other via the short ring 51. In dividing the pixel circuit board 1 into pieces, the short ring 51 is separated from the pixel circuit board 1 along a separation line 50. Consequently, the first power supply line 14, the second power supply line 15, and the auxiliary power supply line 33 are electrically separated from each other as illustrated in FIG. 3.

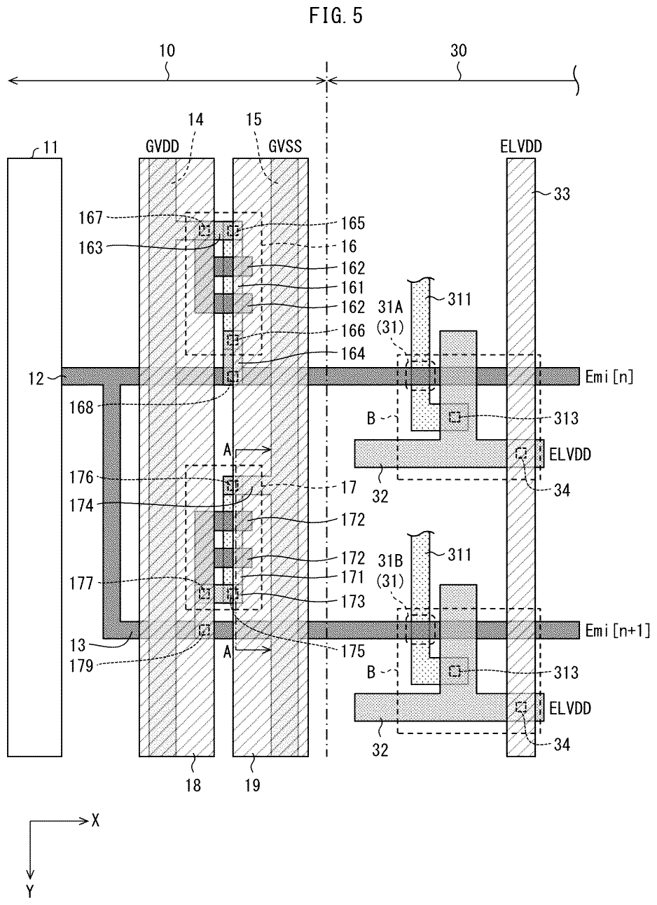

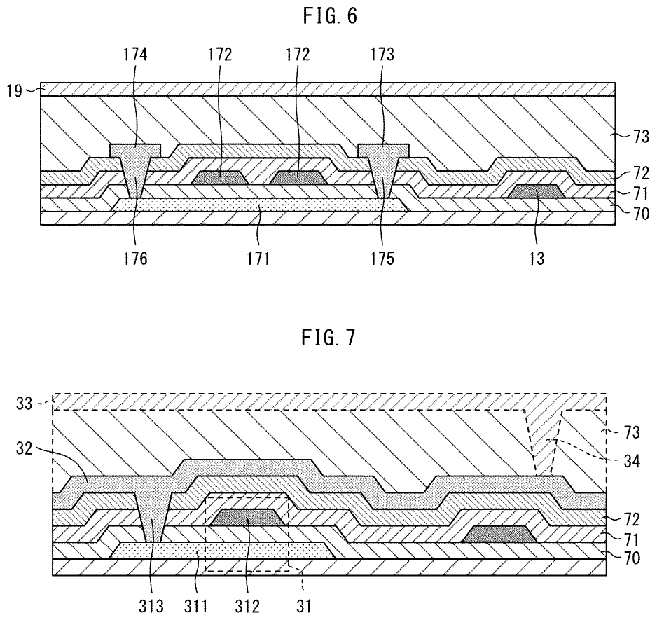

FIG. 5 is a plan view illustrating an example of the pixel circuit board in accordance with the embodiment of the present disclosure. FIG. 6 is a cross-sectional view taken along line A-A in FIG. 5. As shown in FIG. 6, a gate electrode 172 of the second protection transistor 17 is provided above a channel 171 of the second protection transistor 17 via a gate insulation film 70. A drain electrode 173 and a source electrode 174 of the second protection transistor 17 are provided above a gate electrode 172 of the second protection transistor 17 via insulation films 71 and 72. The drain electrode 173 of the second protection transistor 17 is electrically connected with the channel 171 of the second protection transistor 17 via a contact hole 175. The source electrode 174 of the second protection transistor 17 is electrically connected with the channel 171 of the second protection transistor 17 via a contact hole 176.

The drain electrode 173 and the source electrode 174 of the second protection transistor 17 are provided in a layer in which the first power supply line 14 is provided. As illustrated in FIG. 6, a second initialization line 19 is provided above the drain electrode 173 and the source electrode 174 of the second protection transistor 17 via an organic insulation film 73. A first initialization line 18 is provided above the first power supply line 14 (not illustrated in FIG. 6) via the organic insulation film 73. The second power supply line 15 is provided in the layer in which the first power supply line 14 is provided and is made of the same material as that of the first power supply line 14. The second initialization line 19 is provided above the second power supply line 15 (not illustrated in FIG. 6). The second initialization line 19 is provided in a layer in which the first initialization line 18 is provided and is made of the same material as that of the first initialization line 18.

As illustrated in FIG. 5, the gate electrode 172 and the drain electrode 173 of the second protection transistor 17 are electrically connected with each other via a contact hole 177. The contact hole 177 is provided under the first initialization line 18, and overlaps the first initialization line 18 in a plan view.

The second control line 13 is provided in a layer in which the gate electrode 172 of the second protection transistor 17 is provided, and is made of the same material as that of the gate electrode 172. That is, the drain electrode 173 of the second protection transistor 17 is provided in the layer upward of the second control line 13. The drain electrode 173 of the second protection transistor 17 is electrically connected with the second control line 13 via a contact hole 178. The contact hole 179 is provided under the first initialization line 18, and overlaps the first initialization line 18 in a plan view.

The second protection transistor 17 is provided in the layer downward of the first initialization line 18 and the second initialization line 19. In a plan view, the second protection transistor 17 overlaps the first initialization line 18, the second initialization line 19, and an area between the first initialization line 18 and the second initialization line 19. Therefore, even in a case where the second protection transistor 17 is formed in the pixel circuit board 1, this would not increase an area of the inactive area 10 of the pixel circuit board 1.

A channel 161 of the first protection transistor 16 illustrated in FIG. 5 is provided in a layer in which a channel 171 of the second protection transistor 17 is provided, and is made of the same material as that of the channel 171. For example, the channel 161 of the first protection transistor 16 and the channel 171 of the second protection transistor 17 are made of a material containing polysilicon.

A gate electrode 162 of the first protection transistor 16 is provided in the layer in which the gate electrode 172 of the second protection transistor 17 is provided, and is made of the same material as that of the gate electrode 172. For example, the gate electrode 162 of the first protection transistor 16 and the gate electrode 172 of the second protection transistor 17 are made of a material containing molybdenum.

A drain electrode 163 and a source electrode 164 of the first protection transistor 16 are provided in the layer in which the drain electrode 173 and the source electrode 174 of the second protection transistor 17 are provided, and is made of the same material as those of the drain electrode 173 and the source electrode 174. For example, the drain electrode 163 and the source electrode 164 of the first protection transistor 16 and the drain electrode 173 and the source electrode 174 of the second protection transistor 17 are made of a material containing aluminum.

That is, the gate electrode 162 of the first protection transistor 16 is provided above the channel 161 of the first protection transistor 16 via the gate insulation film 70. The drain electrode 163 and the source electrode 164 of the first protection transistor 16 are provided above the gate electrode 162 of the first protection transistor 16 via the insulation films 71 and 72.

The drain electrode 163 of the first protection transistor 16 is electrically connected with the channel 161 of the first protection transistor 16 via a contact hole 165. The source electrode 164 of the first protection transistor 16 is electrically connected with the channel 161 of the first protection transistor 16 via a contact hole 166.

The gate electrode 162 and the drain electrode 163 of the first protection transistor 16 are electrically connected with each other via a contact hole 167. The contact hole 167 is provided under the first initialization line 18, and overlaps the first initialization line 18 in a plan view.

The first control line 12 is provided in the layer in which the gate electrode 162 of the first protection transistor 16 is provided, and is made of the same material as that of the gate electrode 162. That is, the drain electrode 163 of the first protection transistor 16 is provided in the layer upward of the first control line 12. The drain electrode 163 of the first protection transistor 16 is electrically connected with the first control line 12 via a contact hole 168.

The drain electrode 163 and the source electrode 164 of the first protection transistor 16 are provided in the layer in which the first power supply line 14 is provided. The second initialization line 19 is provided above the drain electrode 163 and the source electrode 164 of the first protection transistor 16 via the organic insulation film 73.

The first protection transistor 16 is provided in the layer downward of the first initialization line 18 and the second initialization line 19. In a plan view, the first protection transistor 16 overlaps the first initialization line 18, the second initialization line 19, and an area between the first initialization line 18 and the second initialization line 19. Therefore, even in a case where the first protection transistor 16 is formed in the pixel circuit board 1, this would not increase the area of the inactive area 10 of the pixel circuit board 1.

In a process of forming the power supply transistor 31 in the active area 30 of the pixel circuit board 1, the first protection transistor 16 and the second protection transistor 17 are formed in the inactive area 10 of the pixel circuit board 1.

The following will describe, with reference to FIG. 7, the process of forming the power supply transistor 31. FIG. 7 is a view schematically illustrating an area B in FIG. 5 observed during the process of forming the power supply transistor 31. A gate electrode 312 of the power supply transistor 31 is provided above a channel 311 of the power supply transistor 31 via the gate insulation film 70. For example, the gate electrode 312 of the first power supply transistor 31A and the second power supply transistor 31B is provided in a layer upward of the channel 311 of the first power supply transistor 31A. The gate electrode 312 of the power supply transistor 31 is electrically connected with the first control line 12 or the second control line 13.

The pixel power supply line 32 is provided above the gate electrode 312 of the power supply transistor 31 via the insulation films 71 and 72. For example, the pixel power supply line 32 is provided in a layer upward of the gate electrode 312 of the first power supply transistor 31A. The pixel power supply line 32 and the channel 311 of the power supply transistor 31 are electrically connected with each other via a contact hole 313.

In the forming process illustrated in FIG. 7, the auxiliary power supply line 33 is provided in a layer upward of the pixel power supply line 32, although the auxiliary power supply line 33 is not completely formed yet. Between the pixel power supply line 32 and the auxiliary power supply line 33, the organic insulation film 73 is provided. The pixel power supply line 32 and the auxiliary power supply line 33 are electrically connected with each other via a contact hole 34. The auxiliary power supply line 33 is provided in the layer in which the first initialization line 18 and the second initialization line 19 are provided. The auxiliary power supply line 33, the first initialization line 18, and the second initialization line 19 are made of, for example, a material containing aluminum.

In a process of forming the channel 311 of the power supply transistor 31 in the active area 30, the channel 161 of the first protection transistor 16 and the channel 171 of the second protection transistor 17 illustrated in FIG. 6 are formed in the inactive area 10. The channel 311 of the power supply transistor 31 is made of a material containing polysilicon. The channel 161 of the first protection transistor 16 and the channel 171 of the second protection transistor 17 are provided in the layer in which the channel 311 of the power supply transistor 31 is provided, and are made of the same material as that of the channel 311.

In a process of forming the gate electrode 312 of the power supply transistor 31 in the active area 30, the first control line 12 and the second control line 13 as well as the gate electrode 162 of the first protection transistor 16 and the gate electrode 172 of the second protection transistor 17 illustrated in FIG. 6 are formed in the inactive area 10. The gate electrode 312 of the power supply transistor 31 is made of a material containing molybdenum. The first control line 12, the second control line 13, the gate electrode 162 of the first protection transistor 16, and the gate electrode 172 of the second protection transistor 17 are also provided in the layer in which the gate electrode 312 of the power supply transistor 31 is provided, and is made of the same material as that of the gate electrode 312.

In a process of forming the pixel power supply line 32 and the contact hole 313 in the active area 30, the first power supply line 14, the second power supply line 15, the drain electrode 163 and the source electrode 164 of the first protection transistor 16, and the drain electrode 173 and the source electrode 174 of the second protection transistor 17 illustrated in FIG. 6 are formed in the inactive area 10. That is, the first power supply line 14 and the second power supply line 15 are provided in the layer upward of the gate electrode 312 of the first power supply transistor 31A (FIG. 7). In a process of forming the power supply transistor 31 in the active area 30, the first protection transistor 16 and the second protection transistor 17 are formed in the inactive area 10. The first power supply line 14, the second power supply line 15, and the pixel power supply line 32 are made of a material containing aluminum. The first power supply line 14, the second power supply line 15, the drain electrode 163 and the source electrode 164 of the first protection transistor 16, and the drain electrode 173 and the source electrode 174 of the second protection transistor 17 are also provided in the layer in which the pixel power supply line 32 is provided, and are made of the same material as that of the pixel power supply line 32.

As discussed above, in a process of forming the first power supply transistor 31A and the second power supply transistor 31B, (a) the first protection transistor 16 which resides in the inactive area 10 and which is electrically connected with the first control line 12 and the first power supply line 14 and (b) the second protection transistor 17 which resides in the inactive area 10 and which is electrically connected with the second control line 13 and the second power supply line 15 are formed.

In the process of manufacturing the first control line 12 and the second control line 13, electric charge may sometimes be accumulated in the first control line 12 and the second control line 13. For example, assume that electric charge is accumulated in the first control line 12 when the first protection transistor 16 and the second protection transistor 17 are not formed yet. In this case, when the channel 311 is connected with the pixel power supply line 32 via the contact hole 313, insulation given by the gate insulation film 70 may be broken and electric discharge from the gate electrode 312 to the channel 311 may occur. As described later, in the pixel circuit board 1, the first protection transistor 16 and the second protection transistor 17 reduce a potential difference between (a) potentials of the first control line 12 and the second control line 13 and (b) a potential of the pixel power supply line 32, thereby suppressing electric discharge.

### (1) When Positive Electric Charge is Accumulated in the First Control Line 12 and the Second Control Line 13

In a case where positive electric charge is accumulated in the first control line 12 and the second control line 13, negative voltage is applied between the gate electrode 162 and the source electrode 164 of the first protection transistor 16, whereby the first protection transistor 16 is brought into ON state. An electric current flows between the drain electrode 163 and the source electrode 164 of the first protection transistor 16, so that the potential difference between (a) the potentials of the first control line 12 and the second control line 13 and (b) the potential of the pixel power supply line 32 are reduced.

### (2) When Negative Electric Charge is Accumulated in the First Control Line 12 and the Second Control Line 13

In a case where negative electric charge is accumulated in the first control line 12 and the second control line 13, negative voltage is applied between the gate electrode 172 and the source electrode 174 of the second protection transistor 17, whereby the second protection transistor 17 is brought into ON state. An electric current flows between the drain electrode 173 and the source electrode 174 of the second protection transistor 17, so that the potential difference between (a) the potentials of the first control line 12 and the second control line 13 and (b) the potential of the pixel power supply line 32 are reduced.

Thanks to the configuration in which the pixel circuit board 1 includes the first protection transistor 16 and the second protection transistor 17, a potential difference between (a) potentials of the first control line 12 and the second control line 13 and (b) a potential of the pixel power supply line 32 is reduced when electric charge is accumulated in the first control line 12 and the second control line 13. This makes it possible to prevent breakage of insulation given by the gate insulation film 70.

In the pixel circuit board 1, in the process of forming the power supply transistor 31, the first power supply line 14, the second power supply line 15, and the auxiliary power supply line 33 are electrically connected with each other via the short ring 51. Therefore, with the configuration in which the first protection transistor 16 and the second protection transistor 17 are included, it is also possible to reduce a potential difference between a potential of the auxiliary power supply line 33 and a potential of the pixel power supply line 32. Consequently, even when the auxiliary power supply line 33 is connected with the pixel power supply line 32 via the contact hole 34, it is possible to prevent breakage of insulation given by the gate insulation film 70.

Furthermore, by separating the short ring 51 from the pixel circuit board 1 in the process of dividing the pixel circuit board 1 into pieces, the first power supply line 14, the second power supply line 15, and the auxiliary power supply line 33 are electrically isolated from each other. After the short ring 51 is separated, the first protection transistor 16 and the second protection transistor 17 would not be brought into ON state. Thus, after the pixel circuit board 1 is separated into pieces, it is possible to use the first power supply line 14, the second power supply line 15, and the auxiliary power supply line 33 for their original purposes.

As discussed above, thanks to the configuration in which the pixel circuit board 1 includes the first protection transistor 16 and the second protection transistor 17, it is possible to prevent breakage of insulation given by the gate insulation film 70, without increasing the area of the inactive area 10.

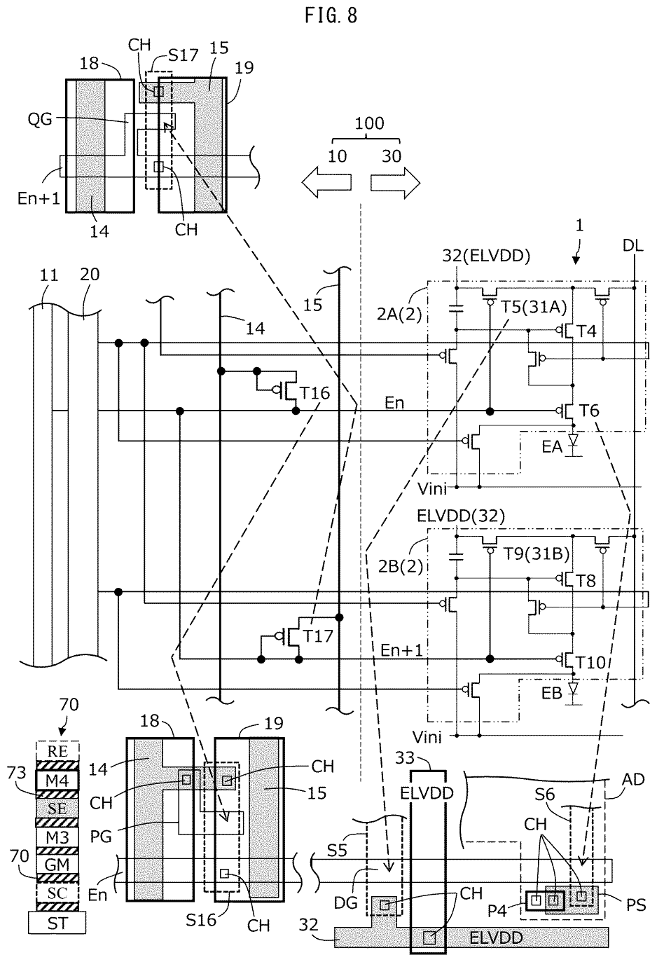

FIG. 8 is an explanatory drawing illustrating an example of a pixel circuit board in accordance with an embodiment of the present disclosure. As illustrated in FIG. 8, a display device 100 includes a pixel circuit board 1, a plurality of light emitting elements EA and EB, an active area 30, and an inactive area 10. The pixel circuit board 1 includes: a first power supply line 14 provided in the inactive area 10; a first power supply transistor T5 provided in the active area 30 and electrically connected with a pixel power supply line 32; a first control line En (a part of which functions as a gate electrode of T5) extending from the inactive area 10 to the active area 30 and being electrically connected with a gate electrode DG of the first power supply transistor T5; and a first protection transistor T16 provided in the inactive area 10 and electrically connected with the first control line En and the first power supply line 14.

The pixel circuit board 1 includes a plurality of pixel circuits 2A and 2B, and the pixel circuit 2A is connected with the light emitting element EA. The pixel circuit 2A includes a driving transistor T4, the first power supply transistor T5, and a light-emission control transistor T6. The pixel circuit 2B is connected with the light emitting element EB. The pixel circuit 2B includes a driving transistor T8, a second power supply transistor T9, and a light-emission control transistor T10.

In accordance with the pixel circuit board 1, in a case where large electric charge is accumulated in the first control line En, it is possible to release the electric charge to the first power supply line 14 via the first protection transistor T16. This reduces the possibility that a gate insulation film 70 of the first power supply transistor T5 may be broken by electrostatic charge. Particularly, in a process for manufacturing the pixel circuit board 1, even in a case where large electric charge is accumulated in the long first control line En, connecting the first power supply line 14 to a short ring can release the electric charge to the short ring via the first protection transistor T16 and the first power supply line 14. The short ring and the first power supply line 14 are cut off in a process of dividing the pixel circuit board 1 into pieces. The first protection transistor T16, which is a thin film transistor, has a high degree of freedom in shape, and thus can downsize the inactive area 10, advantageously.

The first protection transistor T16 is, for example, a p-channel transistor, and is configured not to be turned ON when a potential of the first control line En (a light-emission control line connected to the transistors T5 and T6) is within a predetermined range (a range for normal driving) and to be turned ON only when large electric charge exceeding the predetermined range is generated in the first control line En.

The pixel circuit board 1 may be configured such that, in the active area 30 and the inactive area 10, a substrate ST, a semiconductor layer SC (for example, polysilicon), a metal layer GM, a metal layer M3, a metal layer SE, a metal layer M4, and a metal layer (light reflection electrode layer) RE may be provided in this order. The gate insulation film 70 may be provided on the metal layer GM, and the organic insulation film 73 may be provided on the metal layer SE. The first control line En may be included in the metal layer GM, and the first power supply line 14 may be included in the metal layer SE. The semiconductor layer SC may include semiconductor films S5, S6, S16, and S17.

A channel of the first power supply transistor T5 and a channel of the first protection transistor T16 may be provided in the semiconductor layer SC (i.e., may be provided in the same layer and may be made of the same material). A source area and a gate electrode of the first protection transistor T16 may be electrically connected with the first power supply line 14, which is on a high-potential side, and a drain area of the first protection transistor T16 may be electrically connected with the first control line En. For example, one of two conductive areas of the semiconductor film S16 may be connected to the first control line En via a contact hole CH, the other of the two conductive areas may be connected to the first power supply line 14 via the contact hole CH, a channel part interposed between the two conductive areas may overlap a gate electrode PG via the gate insulation film 70, and a gate electrode PG may be connected with the first power supply line 14 via the contact hole CH. The gate electrode PG may be included in the metal layer GM.

A gate electrode of the first light-emission control transistor T6 may be a part of the first control line En, and a drain area of the semiconductor film S6 of the first light-emission control transistor T6 may be connected with a light reflection electrode AD (an anode of a light emitting element EA) of the metal layer RE via a relay electrode PS of the metal layer SE and a relay electrode P4 of the metal layer M4.

The pixel circuit board 1 may include: a second power supply line 15 provided in the inactive area 10; a second power supply transistor T9 provided in the active area 30 and connected with a pixel power supply line 32; a second control line En+1 (a part of which functions as a gate electrode of T15) extending from the inactive area 10 to the active area 30 and being connected with a gate electrode of the second power supply transistor 9; and a second protection transistor T17 provided in the inactive area 10 and connected with the second control line En+1 and the second power supply line 15, and the first control line En and the second control line En+1 may be connected with each other. In this case, light-emission control for the light emitting elements EA and EB is carried out by the same control signal.

A channel of the second power supply transistor T9 and a channel of the second protection transistor T17 may be provided in the semiconductor layer SC (i.e., may be provided in the same layer and may be made of the same material). A source area and a gate electrode of the second protection transistor T17 may be electrically connected with the second control line En+1, and a drain area of the second protection transistor T17 may be electrically connected with the second power supply line 15, which is on a low-potential side. For example, one of two conductive areas of the semiconductor film S17 may be connected to the first control line En+1 via the contact hole CH, the other of the two conductive areas may be connected to the second power supply line 15 via the contact hole CH, a channel part interposed between the two conductive areas may overlap the gate electrode QG via the gate insulation film 70, and the gate electrode QG may extend from the second control line En+1. The gate electrode QG may be included in the metal layer GM.

The second protection transistor T17 is, for example, a p-channel transistor, and is configured not to be turned ON when a potential of the second control line En+1 (a light-emission control line connected to the transistors T9 and T10) is within a predetermined range (a range for normal driving) and to be turned ON only when large electric charge exceeding the predetermined range is generated in the second control line En+1.

Particularly, in the process for manufacturing the pixel circuit board 1, even in a case where large negative electric charge is accumulated in the first control line En and the second control line En+1 connected with each other, connecting the first power supply line 14 and the second power supply line 15 to the short ring can release the electric charge to the short ring via the second protection transistor T17 (p-channel). Furthermore, even in a case where large positive electric charge is accumulated in the first control line En and the second control line En+1, it is possible to release the electric charge to the short ring via the first protection transistor T16 (p-channel).

The first power supply line 14 and the pixel power supply line 32 may be provided in the metal layer SE (i.e., may be provided in the same layer and may be made of the same material). The first control line En, the gate electrode DG of the first power supply transistor T5, and the gate electrode PG of the first protection transistor 16 may be provided in the metal layer GM (i.e., may be provided in the same layer and may be made of the same material).

The gate electrode DG of the first power supply transistor T5 may be provided in the layer upward of the channel of the first power supply transistor T5, and the first power supply line 14 and the pixel power supply line 32 may be provided in the layer upward of the gate electrode DG of the first power supply transistor. The semiconductor layer SC including the channel of the first power supply transistor T5 may contain polysilicon, the metal layer GM including the gate electrode of the first power supply transistor T5 may contain molybdenum, and the metal layer SE including the first power supply line 14 and the pixel power supply line 32 may contain aluminum. An auxiliary power supply line 33 (ELVDD) connected with the pixel power supply line 32 via the contact hole CH may be provided in a layer upward of the pixel power supply line 32.

A first initialization line 18 may be provided above the first power supply line 14 via an organic insulation film 73, and a second initialization line 19 may be provided above the second power supply line 15 via the organic insulation film 73. In a plan view, the first initialization line 18 and the second initialization line 19 may overlap the gate electrode PG. In a plan view, the second initialization line 19 may overlap the semiconductor film S16. The auxiliary power supply line 33 as well as the first initialization line 18 and the second initialization line 19 may be provided in the same layer.

The foregoing disclosure has been made for the purpose of giving examples and explanations, rather than for the purpose of limitation. On the basis of these examples and explanations, many modified embodiments are obvious to persons skilled in the art. Therefore, such modified embodiments are also encompassed in embodiments of the present disclosure.

### REFERENCE SIGNS LIST

1: pixel circuit board
2: pixel circuit
10: inactive area
11: driver circuit
13: second control line
14: first power supply line
15: second power supply line
16: first protection transistor
17: second protection transistor
18: first initialization line
19: second initialization line
30: active area
31A: first power supply transistor (T5)
31B: second power supply transistor (T9)
32: pixel power supply line
33: auxiliary power supply line
73: organic insulation film
100: display device
161, 171, 311: channel
162, 172, 312: gate electrode
163, 173: drain electrode
164, 174: source electrode
EA, EB: light emitting element

1. A pixel circuit board comprising:
an active area including a plurality of pixel circuits;
an inactive area provided along an outer periphery of the active area;
a first power supply line which is provided in the inactive area;
a first power supply transistor which is provided in the active area and which is electrically connected with a pixel power supply line;
a first control line which extends from the inactive area to the active area and which is electrically connected with a gate electrode of the first power supply transistor; and
a first protection transistor which is provided in the inactive area and which is electrically connected with the first control line and the first power supply line.

2. The pixel circuit board according to claim 1, further comprising:
a second power supply line which is provided in the inactive area;
a second power supply transistor which is provided in the active area and which is electrically connected with the pixel power supply line;
a second control line which extends from the inactive area to the active area and which is electrically connected with a gate electrode of the second power supply transistor; and
a second protection transistor which is provided in the inactive area and which is electrically connected with the second control line and the second power supply line,
the first control line and the second control line being electrically connected with each other.

3. The pixel circuit board according to claim 2, wherein:
one of two conduction terminals and a control terminal of the first protection transistor are electrically connected with the first power supply line, and one of two conduction terminals and a control terminal of the second protection transistor are electrically connected with the first control line.

4. The pixel circuit board according to claim 1, wherein:
a channel of the first power supply transistor and a channel of the first protection transistor are provided in a same layer and are made of a same material.

5. The pixel circuit board according to claim 1, wherein:
the first power supply line and the pixel power supply line are provided in a same layer and are made of a same material.

6. The pixel circuit board according to claim 1, wherein:
the first control line, a gate electrode of the first power supply transistor, and a gate electrode of the first protection transistor are provided in a same layer and are made of a same material.

7. The pixel circuit board according to claim 1, wherein:
the layer in which the gate electrode of the first power supply transistor is provided is upward of the channel of the first power supply transistor; and
the layer in which the first power supply line and the pixel power supply line are provided is upward of the gate electrode of the first power supply transistor.

8. The pixel circuit board according to claim 7, wherein:
a layer in which an auxiliary power supply line electrically connected with the pixel power supply line is provided is upward of the pixel power supply line.

9. The pixel circuit board according to claim 8, wherein:
a first initialization line is provided above the first power supply line via an organic insulation film.

10. The pixel circuit board according to claim 9, wherein:
the auxiliary power supply line and the first initialization line are provided in a same layer.

11. The pixel circuit board according to claim 2, wherein:
the inactive area includes a driver circuit; and
the first control line is connected with the driver circuit.

12. The pixel circuit board according to claim 11, wherein:
the first power supply line is a high-potential power supply line for the driver circuit; and
the first protection transistor is of a p-channel type, and the first protection transistor has a source electrode, a drain electrode, and a gate electrode, one of the source electrode and the drain electrode being electrically connected with the first control line, the other of the source electrode and the drain electrode as well as the gate electrode being electrically connected with the first power supply line.

13. The pixel circuit board according to claim 12, wherein:
the second power supply line is a low-potential power supply line for the driver circuit; and
the second protection transistor is of a p-channel type, and the second protection transistor has a source electrode, a drain electrode, and a gate electrode, one of the source electrode and the drain electrode being electrically connected with the second power supply line, the other of the source electrode and the drain electrode as well as the gate electrode being electrically connected with the second control line.

14. The pixel circuit board according to claim 7, wherein:
the channel of the first power supply transistor contains polysilicon;
the gate electrode of the first power supply transistor contains molybdenum; and
the first power supply line and the pixel power supply line contain aluminum.

15. The pixel circuit board according to claim 3, wherein:
a second initialization line is provided above the second power supply line via an organic insulation film.

16. A display device comprising:
a plurality of light emitting elements; and
a pixel circuit board recited in claim 1.

17. The display device according to claim 16, wherein:
the first control line is a light-emission control line that carries out light-emission control for a single sub pixel row.

18. A method for producing a pixel circuit board that includes a first power supply line provided in an inactive area, a first power supply transistor provided in an active area and electrically connected with a pixel power supply line, and a first control line extending from the inactive area to the active area and being electrically connected with a gate electrode of the first power supply transistor, the method comprising:
forming, in a process of forming the first power supply transistor, a first protection transistor in the inactive area, the first protection transistor being connected with the first control line and the first power supply line.

19. The method according to claim 18, wherein:
the first power supply line is connected with a short ring until the pixel circuit board is divided into pieces.
